(19) United States
(12) Patent Application Publication
(10) Pub. No.: US 2009/0026587 A1
(43) Pub. Date: Jan. 29, 2009

(54) GRADIENT DEPOSITION OF LOW-K CVD MATERIALS

(75) Inventors: Matthew Angyal, Stormville, NY (US); Habib Hichri, Wappingers Fall, NY (US); Henry A. Nye, III, Brookfield, CT (US); Dale McHerron, Staatsburg, NY (US); Jia Lee, Ossining, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/597,038

(22) PCT Filed: Jan. 14, 2004
(86) PCT No.: PCT/US04/00908

§ 371 Date: Jul. 7, 2006

(51) Int. Cl. H01L 23/58; H01L 21/31

(52) U.S. Cl. 257/632; 438/778; 257/E23.002

(57) ABSTRACT

A dielectric layer for a semiconductor device having a low overall dielectric constant, good adhesion to the semiconductor substrate, and good resistance to cracking due to thermal cycling. The dielectric layer is made by a process involving continuous variation of dielectric material deposition conditions to provide a dielectric layer having a gradient of dielectric constant.

### TECHNICAL FIELD

The present invention relates generally to semiconductor devices, and, more particularly, to dielectric layers for such devices having a low overall dielectric constant, good adhesion to the semiconductor substrate, and good resistance to cracking due to thermal cycling, and to processes for making such dielectric layers.

### BACKGROUND OF THE INVENTION

Insulating dielectric layers, commonly referred to as inter-level dielectrics (ILD's), are used to separate conductor and semiconductor layers within semiconductor devices. Recently, dielectric materials having low dielectric constants, k, known as “low-k dielectrics,” have become popular because they create less capacitance between and around the conductors and are more easily applied than conventional silicon oxide dielectrics, which have higher dielectric constants. Recent progress in low-k dielectrics, for example using Chemical Vapor Deposition (“CVD”) techniques, offers more affordable and attractive dielectric options to the advanced interconnect technologies. CVD is a process for depositing a thin film of material onto a substrate by reacting the constituent elements in gaseous phase; CVD processes are used to produce thin, single-crystal films called epitaxial films. By employing CVD low-k dielectrics with a dielectric constant of about 2.7 at the wiring level, the total capacitance and RC delay can be significantly reduced.

One common problem encountered when using low-k dielectrics is poor adhesion, however, between the low-k dielectrics and the underlying substrate. Conventional methods typically form low-k dielectric films through either spin-on processes or through Plasma Enhanced Chemical Vapor Deposition (PECVD) of organosilane gases, to produce dielectrics such as amorphous hydrogenated carbon doped oxide (a-SiCO:H) or other carbon-containing dielectrics such as are known in the art. Such dielectrics often have poor adhesion to substrates such as silicon dioxide, silicon nitride, silicon carbide, silicon, tungsten, aluminum, and copper. Because of this low structural adhesion, low-k dielectric layers often delaminate from the underlying substrate, which leads to a failure of interconnect processes.

One conventional method to improve adhesion between low-k dielectric layers and underlying substrates is the use of an adhesion promoter. An adhesion promoter is often used for spin-on dielectric (SOD) low-k dielectrics rather than for PECVD processes, however, which requires the use of a precursor such as methylsilane (1MS) trimethylsilane (3MS), tetramethylsilane (4MS), tetramethylcyclotetrasiloxane (TMCTS), and/or orthomethylcyclotetrasiloxane (OMCTS). Such low-k dielectric films have, in general, a hydrophobic surface with high wetting angles with water. This characteristic causes these films to have a very poor adhesion with substrate layers.

Hybrid stacks of dielectric material have also been used in making semiconductor devices, in which the ILD comprises two or more discrete films of different dielectric materials. Such hybrid schemes usually employ a low-k material at the trench level, and a strong and thermally compatible material (lower thermal expansion) at the via level, typically having a higher dielectric constant than the material used at the trench level. The incorporation of two or more discrete dielectric films in this manner increases the number of steps required in the process of forming the ILD, and the resulting device may suffer from adhesion problems between the films.

Therefore, there is a need for structures and methods that provide ILD's with low overall k and that provide good adhesion between the ILD and the substrate, as well as resistance to internal adhesion failure of the ILD.

### SUMMARY OF THE INVENTION

To meet this and other needs, and in view of its purposes, the present invention provides, in one aspect, a dielectric layer disposed on a substrate surface. The dielectric layer has a top surface. The dielectric layer comprises a first dielectric gradient region in which a dielectric constant k decreases continuously from a maximum value to a minimum value with distance from the substrate surface.

In another aspect, the invention provides a process of making a dielectric layer disposed on a substrate surface. The process comprises applying to the substrate, via chemical vapor deposition, a continuously varying composition of chemical vapor deposition precursors to form a first dielectric gradient region in which a dielectric constant k decreases continuously from a maximum value to a minimum value with distance from the substrate surface.

In a further aspect, the invention provides a process of making a semiconductor device that comprises a dielectric layer disposed on a substrate surface. The process comprises applying to the substrate, via chemical vapor deposition, a continuously varying composition of chemical vapor deposition precursors to form a first dielectric gradient region in which a dielectric constant k decreases continuously from a maximum value to a minimum value with distance from the substrate surface.

It is to be understood that both the foregoing general description and the following detailed description are exemplary, but are not restrictive, of the invention.

### BRIEF DESCRIPTION OF THE DRAWING

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a cross sectional view of a portion of a patterned inter-level dielectric layer on a substrate, according to the present invention;

FIG. 2 is a graphical representation of the profile of variation of dielectric constant in the inter-level dielectric layer of FIG. 1, according to one embodiment of the invention;

FIG. 3 is a graphical representation of the profile of variation of dielectric constant in the inter-level dielectric layer of FIG. 1, according to a second embodiment of the invention;

FIG. 4 is a graphical representation of the profile of variation of dielectric constant in the inter-level dielectric layer of FIG. 1, according to another embodiment of the invention;

FIG. 5 is a graphical representation of the profile of variation of dielectric constant in the inter-level dielectric layer of FIG. 1, according to yet another embodiment of the invention; and

FIG. 6 is a graphical representation of the profile of variation of dielectric constant in the inter-level dielectric layer of FIG. 1, according to a further embodiment of the invention.

### DETAILED DESCRIPTION OF THE INVENTION

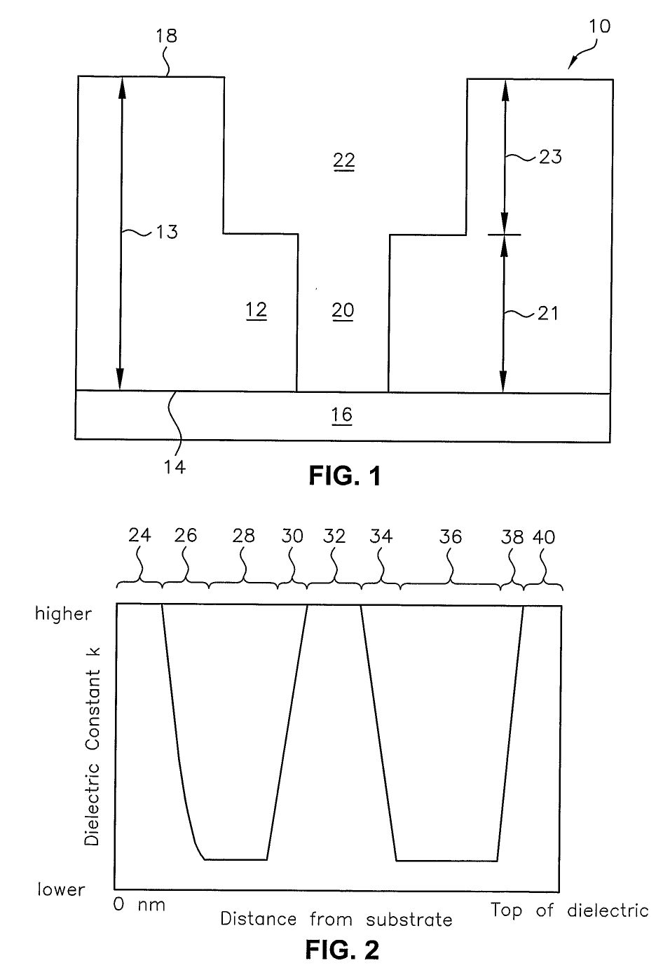

Referring now to the drawing, in which like reference numbers refer to like elements throughout the various figures that comprise the drawing, FIG. 1 shows in cross sectional view a portion of a patterned inter-level dielectric layer (ILD), indicated generally at 10, according to the invention. The ILD comprises a dielectric layer 12 disposed on a surface 14 of a substrate 16. Dielectric layer 12 has a top surface 18, and has within in it a hollow space at each of a via 20 and a trench 22. Via 20 and trench 22 have depths indicated at 21 and 23, respectively. A section of dielectric layer 12 in which there is no trench or via is indicated at 13. Substrate 16 may be any common substrate used in integrated circuit chips. For example, substrate 16 may comprise a pure silicon (single crystal or polycrystalline), silicon dioxide, silicon nitride, silicon carbide, tungsten, aluminum, copper, and the like.

FIG. 2 is a graphical representation of the profile of variation of dielectric constant k in dielectric layer 12 of FIG. 1, as a function of distance from the substrate surface 14, in a section of the device of FIG. 1 in which there is no via 20 or trench 22 (section 13 in FIG. 1), according to one embodiment of the invention. Dielectric layer 12 comprises an optional initial dielectric region 24 adjacent the substrate surface 14. Although FIG. 2 shows initial dielectric region 24 as having a constant value of k throughout, the value of the dielectric constant need not be constant. As used in this document, the term “optional” as applied to a dielectric region means that the profile of dielectric constant shown for the dielectric material in that region is optional. It is to be understood that the presence of a dielectric material is required in all regions of dielectric layer 12, except where via 20 or trench 22 is present, as shown in FIG. 1. In one embodiment of the invention, initial dielectric region 24 extends from substrate surface 14 and has a thickness equal to the depth 21 of via 20.

Adjacent the initial dielectric region 24 is a dielectric gradient region 26, in which the dielectric constant decreases continuously with distance from substrate surface 14. Adjacent to dielectric gradient region 26 is an optional dielectric region 28, in which k has an optionally variable value less than the highest level of k in dielectric gradient region 26, followed by an optional dielectric gradient region 30 in which k increases with distance from substrate surface 14.

Adjacent dielectric gradient region 30 is an optional dielectric region 32 in which k may or may not be equal to the highest level of k in dielectric gradient region 26, and in which k may be variable. Adjacent dielectric region 32 is an optional dielectric gradient region 34 in which k decreases with distance from substrate surface 14. Dielectric region 32 and adjacent dielectric regions 30 and 34 may be present in locations other than at the interface of trench 22 and via 20, or they may be totally absent altogether. In one embodiment, however, these regions may serve as an etch stop to facilitate formation of trench 22 after formation of via 20 in a dual damascene process.

A damascene process is a process used in some aspects of semiconductor fabrication. It is a process of inlaying a metal into a predefined pattern, typically in a dielectric layer. It is typically performed by defining the desired pattern into a dielectric film; depositing metal over the entire surface by either physical vapor deposition, chemical vapor deposition, or evaporation; then polishing back the top surface in such a way that the top surface is planarized and the metal pattern is only located in the predefined regions of the dielectric layer. The damascene process has been used in manufacturing of metal wiring lines, including the bit-lines for a Dynamic Random Access Memory (“DRAM”) capacitor.

Damascene technology is a common method of fabricating interconnects. In this context, damascene refers to the steps of patterning an insulator to form recesses, filling the recesses with a metal, and then removing the excess metal above the recesses. This process can be repeated as needed to form the desired number of stacked interconnects. Typically, these damascene structures are laid out in pairs, a process referred to as dual damascene.

The term “damascene” is derived from the name of a centuries' old process used to fabricate a type of in-laid metal jewelry first seen in the city of Damascus. In the context of integrated circuits, damascene means formation of a patterned layer imbedded on and in another layer such that the top surfaces of the two layers are coplanar. Planarity is essential to the formation of fine-pitch interconnect levels because lithographic definition of fine features is achieved using high-resolution steppers having small depths of focus. The “dual damascene” process, in which conductive lines and stud via metal contacts are formed simultaneously, is described by Chow in U.S. Pat. No. 4,789,648.

Adjacent dielectric gradient region 34 is an optional dielectric region 36, in which k has an optionally constant value that is lower than the highest level of k in dielectric gradient region 26 and that may or may not be the same as the value of k in dielectric region 28. Adjacent dielectric region 36 is an optional dielectric gradient region 38 in which k increases with distance from substrate surface 14. Adjacent dielectric gradient region 38 is an optional dielectric region 40 having an optionally constant k that may or may not be equal to either of the highest level of k in dielectric gradient region 26 or the value of k in dielectric region 32. Dielectric region 40 may serve, for example, as a cap for dielectric layer 12, to seal it.

Although some of the dielectric gradient regions shown in FIG. 2 have a linear profile, and some have a nonlinear profile, either a linear or nonlinear profile may be used for any gradient region. Only first dielectric gradient region 26 is required to be present according to the invention. In one embodiment of the invention, the lowest value of k in the first dielectric gradient region 26, which in the embodiment shown in FIG. 2 is at the point where dielectric gradient region 26 adjoins dielectric region 28, represents a reduction of at least 0.2 relative to the highest level of k in dielectric gradient region 26.

Typically, the instantaneous rate of decrease of k in the first dielectric gradient region 26 is between 0.025 and 0.5 per 10 nm of dielectric thickness at substantially every location throughout it. This rate provides good adhesion between dielectric layer 12 and substrate 16 as well as high resistance to internal cracking within dielectric layer 12, for example due to thermal cycling. Advantageously, other dielectric gradient regions such as 30, 34, and 38 may also have instantaneous rates of increase or decrease of k between 0.025 and 0.5 per 10 nm of dielectric thickness, for the same reasons.

In one embodiment of the invention, the instantaneous rate of increase or decrease in any or all dielectric gradient regions may be between 0.05 and 0.1 per 10 nm of dielectric thickness. Rates in such a range may provide a good balance between provision of overall low average dielectric constant throughout dielectric layer 12, and prevention of adhesion loss or cracking. Regions of optionally constant k value, such as shown at 24, 28, 32, 36, and 40 in FIG. 2 may be of any thickness as may be convenient for the purposes of the application of interest.

As is well understood in the art, the lowest practical levels of dielectric constant k are generally preferred, to reduce capacitive coupling and resultant cross talk between lines. Therefore, low dielectric constant materials will typically be used in all locations when possible. Similarly, when the use of a higher k material is required for reasons of adhesion, etch stop performance, or for other purposes, the rates of dielectric constant increase or decrease in the dielectric gradient regions will be as high as possible without creating adhesion, cracking, or other problems, so that as much as possible of the total thickness of dielectric layer 12 is of a low k material. The invention is not restricted, however, to the use of low k materials in the dielectric layer 12, nor is it restricted to the particular low k materials used as examples in this document.

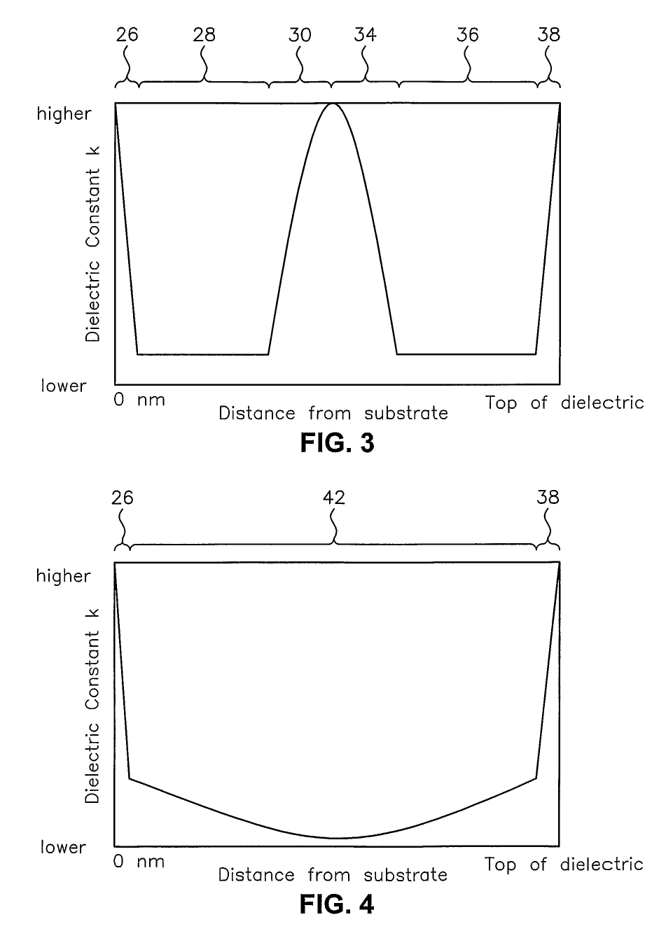

FIG. 3 is a graphical representation of another exemplary profile of variation of dielectric constant k in dielectric layer 12 of FIG. 1, according to the invention. Dielectric layer 12 comprises dielectric gradient regions 26, 30, 34, and 38, and dielectric regions 28 and 36, all as described above in relation to FIG. 2. A profile such as shown in FIG. 3 may provide an etch stop at the point of placement of dielectric gradient regions 30 and 34, as well as an adhesion-promoting region at 26 and a cap at 38, while maintaining a large proportion of low k dielectric in dielectric layer 12.

FIG. 4 is a graphical representation of yet another exemplary profile of variation of dielectric constant k in dielectric layer 12, according to the invention. The dielectric layer 12 comprises dielectric gradient regions 26 and 38, as described above, separated by a dielectric region 42 in which k first decreases and then increases with distance from substrate surface 14.

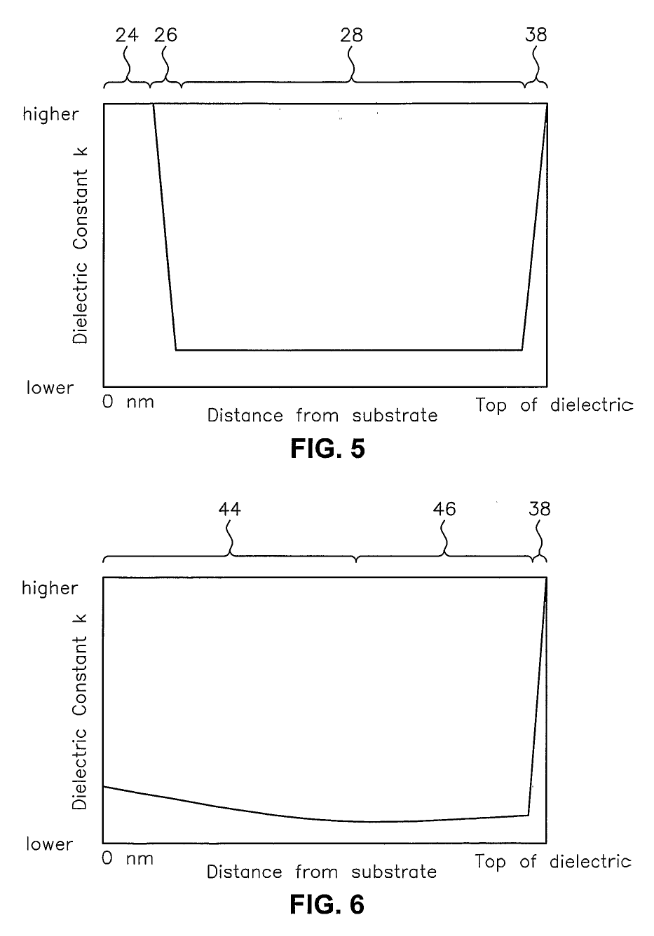

FIG. 5 is a graphical representation of still another exemplary profile of variation of dielectric constant k in dielectric layer 12, according to the invention. The dielectric layer 12 comprises dielectric gradient regions 26 and 38 and dielectric regions 24 and 28, as described above. In this embodiment of the invention, a large proportion of dielectric layer 12 comprises a material of low k value.

FIG. 6 is a graphical representation of a further exemplary profile of variation of dielectric constant k in dielectric layer 12, according to the invention. The dielectric layer 12 comprises dielectric gradient region 38 as described above, preceded by dielectric gradient regions 44 and 46 having decreasing and increasing profiles of k with distance from substrate surface 14, respectively. In this embodiment of the invention, a large proportion of dielectric layer 12 comprises a material of low k value, while the high k material in dielectric gradient region 38 provides a cap for dielectric layer 12.

The materials that constitute the dielectric regions and the dielectric gradient regions disclosed above in relation to FIGS. 1-6 are Chemical Vapor Deposition (CVD) products, including Plasma Enhanced Chemical Vapor Deposition (PECVD) products. In a preferred embodiment of the invention, the dielectric gradient regions comprise materials that are deposited by CVD or PECVD in which the temperatures, pressures, and/or ratios of component materials are varied in a continuous manner to provide gradients in composition, and therefore gradients in k. Variation of these and other parameters to provide materials having different dielectric constants is known in the art for making materials of constant k, but such variation on a continuous basis within a given process to produce an ILD having a gradient of k has not been previously disclosed.

Any of a number of materials may be used to produce ILD's having dielectric gradient regions according to the invention. Such materials, and the processes for applying them, include for example a dielectric material provided by CVD deposition. Such materials are referred to in this document as CVD precursors.

The invention may for example utilize well-known materials such as 1MS, 3MS, 4MS, TMCTS, OMCTS, and the like, which may be used with or without oxygen and/or carbon dioxide as an oxidizer. The invention employs a continuously varying deposition process that gradually increases the concentration of such gases as dielectric material builds upon the substrate 16. This process produces a structure that has a gradient structure of increasing organic concentration, accompanied by decreasing dielectric constant k.

More specifically, in connection with the exemplary embodiment shown in FIG. 5, deposition may start by introducing a first amount of organic gas or gases to form a pure silicon dioxide region at initial dielectric region 24, using tetraethyl orthosilicate or silane under oxidizing conditions well known in the art, which may include an inert gas in addition to the oxidizing gas. Then, formation of dielectric gradient region 26 may be accomplished by introducing, in continuously increasing amounts, one or more of 1MS, 3MS, 4MS, TMCTS, and OMCTS, until a full flow of organic material, with no inert gas, is fed to the process. The process may optionally be modified to include one or more materials capable of generating nanometer-sized voids, using materials such as are disclosed in U.S. Pat. No. 6,479,110 issued to Grill et al. At this point, the dielectric is of a very low k value, and these deposition conditions are maintained for a period of time, generating dielectric region 28. At the end of this time, a sequence that is essentially the reverse of that which formed dielectric gradient region 26 is performed to produce increasing k dielectric gradient region 38.

In the foregoing, the processing pressure in the reactor chamber can be any standard operating pressure and is preferably between about 1 Torr to about 10 Torr and is more preferably about 4 Torr. An RF power source with source power preferably between 300 and 1,000 watts, more preferably about 600 watts, can be used. Any frequency and combination of RF powers can be used for bias power for sputtering in a range of between 0 watts and about 500 watts. The temperature range is preferably about 250° C.-550° C. The thickness of layers 24, 26, 28, and 38 may be any design thickness, and are typically between about 10 nm and 150 nm. Therefore, the total thickness of dielectric layer 12, as shown in FIG. 1, may be between about 50 nm and about 5,000 nm. Variations to these conditions may be used, however, to meet the conditions of particular situations, according to practices and processes well known in the art.

Following the formation of the resulting dielectric layer 12, conventional photolithography and etching processes may be applied to generate etched regions, e.g., vias and/or trenches, for forming contacts, single damascene interconnects, dual damascene interconnects, or other types of interconnects. Such etched regions may be filled with tungsten, copper, copper alloy, aluminum, aluminum alloy, or another conductive material, as is well known to those skilled in the art. Appropriate combinations of these and other steps known in the semiconductor fabrication art can achieve a complete semiconductor device incorporating dielectric gradient regions.

### EXAMPLES

The following examples are included to more clearly demonstrate the overall nature of the invention. These examples are exemplary, not restrictive, of the invention. The following abbreviations are used in the examples.

OMCTS means octamethylcyclotetrasiloxane.

SICOH means amorphous hydrogenated carbon doped silicon oxide.

“Spacing” refers to the distance between the semiconductor wafer and the plasma electrode.

HFRF and LFRF are high and low frequency radio frequencies, respectively, used for forming the plasma. Plasma is a partially ionized gas. To make plasma, a device excites a gas with high radio or microwave frequencies. The plasma then emits light, charged particles (ions and electrons), and neutral active components (atoms, excited molecules, and free radicals). These particles and components bombard substrates brought into the plasma environment.

In Examples 1 and 2, dielectric layers are deposited by PECVD techniques onto a silicon substrate, using the plasma and composition conditions shown.

EXAMPLE 1

| | | First | | Second | |
|---|---|---|---|---|---|
| | Step 1 | Transition | Step 2 | Transition | Step 3 |
| Temperature (° C.) | 350 | 350 | 350 | 350 | 350 |
| Pressure (Torr) | 5 | ramp up | 7 | ramp down | 4-5 |
| Spacing (mils) | 450 | 450 | 450 | 450 | 450 |
| HFRF Power (Watts) | 500 | Note 1 | 500 | Note 2 | 500 |
| LFRF Power (Watts) | 150 | Note 1 | 150 | Note 2 | 150 |
| OMCTS Feed Rate | 2500 | ramp up | 3500 | ramp down | 2000-2500 |
| (mg/minute) | | | | | |
| Helium Feed Rate (sccm) | 1000 | 1000 | 1000 | Note 2 | 1000 |
| Oxygen Feed Rate (sccm) | 160 | 160 | 160 | ramp down | 0 |
| Approximate k obtained | 3 | gradient | ≦2.7 | gradient | 3.3 |

Note 1 -
Optional gradual decrease by 30%, then gradual increase to Step 2 level
Note 2 -
Optional gradual increase by 30%, then gradual decrease to Step 3 level

EXAMPLE 2

| | | First | | Second | |
|---|---|---|---|---|---|
| | Step 1 | Transition | Step 2 | Transition | Step 3 |
| Temperature (° C.) | 350 | 350 | 350 | 350 | 350 |
| Pressure (Torr) | 7 | ramp down | 1 | ramp up | 4-5 |
| Spacing (mils) | 450 | 450 | 450 | 450 | 450 |
| HFRF Power (Watts) | 500 | ramp down | 300 | ramp up | 500 |
| LFRF Power (Watts) | 150 | ramp down | 0 | ramp up | 150 |
| OMCTS Feed Rate | 3500 | ramp down | 150 | ramp up | 2000-2500 |
| (mg/minute) | | | | | |
| Helium Feed Rate (sccm) | 1000 | ramp down | 100 | ramp up | 1000 |
| Oxygen Feed Rate (sccm) | 160 | ramp down | 0 | 0 | 0 |
| Ethylene (mg/minute) | 0 | ramp up | 1800 | ramp down | 0 |
| Approximate k obtained | </=2.7 | gradient | 2.2 | gradient | 3.3 |

In Examples 1 and 2, regions of essentially constant k are produced in each of Steps 1, 2, and 3, while regions having an increasing or decreasing gradient of k are formed during the First and Second Transitions.

What is claimed:

1. A dielectric layer (12) disposed on the surface (14) of a substrate (16), the dielectric layer having a top surface (18), wherein the dielectric layer comprises a first dielectric gradient region (26, 44) in which a dielectric constant k decreases continuously from a maximum value to a minimum value with distance from the substrate surface.

2. The dielectric layer (12) according to claim 1 wherein an instantaneous rate of decrease of k in the first dielectric gradient region (26) is between 0.025 and 0.5 per 10 nm of the dielectric thickness (13) at substantially every location throughout the first dielectric gradient region (26).

3. The dielectric layer (12) according to claim 1 wherein an instantaneous rate of decrease of k in the first dielectric gradient region (26) is between 0.05 and 0.1 per 10 nm of the dielectric thickness (13) at substantially every location throughout the first dielectric gradient region (26).

4. The dielectric layer (12) according to claim 1 wherein the minimum value of k in the first dielectric gradient region (26) represents a reduction of at least 0.2 relative to the maximum value.

5. The dielectric layer (12) according to claim 1 wherein the minimum value of k in the first dielectric gradient region (26) represents a reduction of at least 0.5 relative to the maximum value.

6. The dielectric layer (12) according to claim 1 wherein the instantaneous rate of decrease of k in the first dielectric gradient region (26) varies linearly with distance from the substrate surface (14).

7. The dielectric layer (12) according to claim 1 wherein the instantaneous rate of decrease of k in the first dielectric gradient region (26) varies nonlinearly with distance from the substrate surface (14).

8. The dielectric layer (12) according to claim 1 wherein the first dielectric gradient region (26) is adjacent the substrate surface (14).

9. The dielectric layer (12) according to claim 1 wherein the first dielectric gradient region (26) is not adjacent the substrate surface (14), the dielectric layer (12) further comprising an initial dielectric region (24) bounded by the substrate surface (14) and the first dielectric gradient region (26).

10. The dielectric layer (12) according to claim 1 wherein the first dielectric gradient region (26) consists essentially of chemical vapor deposition products.

11. The dielectric layer (12) according to claim 1 wherein the dielectric layer consists essentially of chemical vapor deposition products.

12. The dielectric layer (12) according to claim 1 wherein the dielectric layer further comprises a second dielectric gradient region (30, 38, 46) in which k increases continuously with distance from the substrate surface (14).

13. The dielectric layer (12) according to claim 12 wherein the second dielectric gradient region (30, 38, 46) forms the top surface (18) of the dielectric layer (12).

14. The dielectric layer (12) according to claim 12 wherein the dielectric layer further comprises a third dielectric gradient region (34) in which k decreases continuously with distance from the substrate surface (14), the third dielectric gradient region being farther than the second dielectric gradient region (30) from the substrate surface.

15. The dielectric layer (12) according to claim 14 wherein the third dielectric gradient region (34) is adjacent the second dielectric gradient region (30).

16. The dielectric layer (12) according to claim 14 wherein the third dielectric gradient region (34) is not adjacent the second dielectric gradient region (30), the dielectric layer further comprising an intermediate dielectric region (32) bounded by the second dielectric gradient region (30) and the third dielectric gradient region (34).

16. A semiconductor device comprising a dielectric layer (12) according to claim 1.

17. A process of making a dielectric layer (12) disposed on the surface (14) of a substrate (16), the process comprising applying directly or indirectly to the substrate, under chemical vapor deposition conditions, a continuously varying composition of chemical vapor deposition precursors to form a first dielectric gradient region (26) in which a dielectric constant k decreases continuously from a maximum value to a minimum value with distance from the substrate surface.

18. The process of claim 17 further comprising applying to the substrate an initial dielectric region (24) and then applying the first dielectric gradient region (26) to the substrate.

19. A process of making a semiconductor device that comprises a dielectric layer (12) disposed on a surface (14) of a substrate (16), the process comprising applying directly or indirectly to the substrate, under chemical vapor deposition conditions, a continuously varying composition of chemical vapor deposition precursors to form a first dielectric gradient region (26) in which a dielectric constant k decreases continuously from a maximum value to a minimum value with distance from the substrate surface.

20. The process of claim 19 further comprising applying to the substrate an initial dielectric region (24) and then applying the first dielectric gradient region (26) to the substrate.
